(19) United States
(12) Patent Application Publication
(10) Pub. No.: US 2018/0294168 A1
(43) Pub. Date: Oct. 11, 2018

(54) METHOD FOR ANISOTROPIC DRY ETCHING OF TITANIUM-CONTAINING FILMS

(71) Applicant: Tokyo Electron Limited, Tokyo (JP)

(72) Inventors: Kandabara N. Tapily, Albany, NY (US); Vinayak Rastogi, Albany, NY (US); Alok Ranjan, Albany, NY (US)

(21) Appl. No.: 15/949,745

(22) Filed: Apr. 10, 2018

Related U.S. Application Data
(60) Provisional application No. 62/484,337, filed on Apr. 11, 2017.

(51) Int. Cl. H01L 21/3213

(52) U.S. Cl. CPC H01L 21/32136; H01L 21/32138

(57) ABSTRACT

Methods for anisotropic dry etching of titanium-containing films used in semiconductor manufacturing have been disclosed in various embodiments. According to one embodiment, the method includes providing a substrate having a titanium-containing film thereon, and etching the titanium-containing film by a) exposing the substrate to a chlorine-containing gas to form a chlorinated layer on the substrate, b) exposing the substrate to a plasma-excited inert gas to remove the chlorinated layer, and c) repeating the exposing steps at least once.

### CROSS-REFERENCE TO RELATED APPLICATIONS

This application is related to and claims priority to U.S. Provisional Patent Application Ser. No. 62/484,337, filed on Apr. 11, 2017, the entire contents of which are herein incorporated by reference.

### FIELD OF THE INVENTION

The present invention relates to the field of semiconductor manufacturing and semiconductor devices, and more particularly, to a method of anisotropic dry etching of titanium-containing films.

### BACKGROUND OF THE INVENTION

As smaller transistors are manufactured, the critical dimension (CD) or resolution of patterned features is becoming more challenging to produce. Sub 10 nm technology nodes require strict film thickness, film uniformity, and almost no margin or variations at the atomic level to the design specification. Surfaces and thin films are becoming a significant fraction of the device size and self-limited processes such as Atomic Layer Deposition (ALD) and Atomic Layer Etching (ALE) are becoming indispensable for high volume semiconductor manufacturing.

### SUMMARY OF THE INVENTION

Embodiments of the invention provide a method of anisotropic dry etching of titanium-containing films. According to one embodiment, the method includes providing a substrate having a titanium-containing film thereon, and etching the titanium-containing film by a) exposing the substrate to a chlorine-containing gas to form a chlorinated layer on the substrate, b) exposing the substrate to a plasma-excited inert gas to remove the chlorinated layer, and c) repeating the exposing steps at least once.

According to another embodiment, the method includes providing a substrate containing a recessed feature with a sidewall and a bottom portion, the recessed feature containing a titanium-containing film on the sidewall and on the bottom portion, and removing the titanium-containing film in a dry etching process from the bottom portion, but not from the sidewall, by: a) exposing the substrate to a chlorine-containing gas to form a chlorinated layer on the bottom portion, b) exposing the substrate to a plasma-excited inert gas to remove the chlorinated layer from the bottom portion, and c) repeating the exposing steps at least once.

### BRIEF DESCRIPTION OF THE DRAWINGS

The accompanying drawings, which are incorporated in and constitute a part of this specification, illustrate embodiments of the invention and, together with a general description of the invention given above, and the detailed description given below, serve to explain the invention.

FIG. 1 is a process flow diagram for a method of processing a substrate according to an embodiment of the invention;

FIG. 2 is a process flow diagram for a method of processing a substrate according to an embodiment of the invention;

FIGS. 3A-3G schematically show through cross-sectional views a method of processing a substrate according to an embodiment of the invention; and

FIG. 4 shows TiN etching amounts as a function of number of cycles using alternating exposures of Cl₂ and plasma-excited Ar.

### DETAILED DESCRIPTION OF SEVERAL EMBODIMENTS

Embodiments of the invention provide a method of anisotropic dry etching of titanium-containing films. The dry etching method is a quasi-ALE process where the material removal uses sequential self-limiting reactions. Some embodiments of the invention may be used in integrated process of advanced contacts in order to address the increasing challenge in reducing source/drain (S/D) contact resistivity.

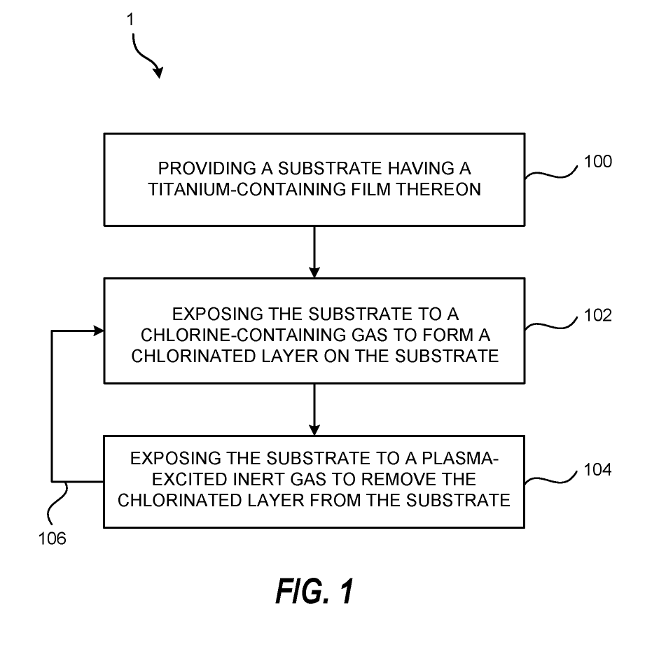

FIG. 1 is a process flow diagram for a method of processing a substrate according to an embodiment of the invention. The method includes providing a substrate having a titanium-containing film thereon. The titanium-containing film can, for example, include Ti metal, TiN, TiC, TiCN, or combinations thereof. The method further includes etching the titanium-containing film by, in 102, exposing the substrate to a chlorine-containing gas to form a chlorinated layer on the substrate and, in 104, exposing the substrate to a plasma-excited inert gas to remove the chlorinated layer from the substrate. The exposure to the chlorine-containing gas may be done in the absence of a plasma or using plasma excitation.

The exposure to the chlorine-containing gas may be performed without plasma excitation in order to prevent plasma damage to the titanium-containing film and any device features on the substrate. The reaction of the chlorine-containing gas with the titanium-containing film that forms the chlorinated layer is self-limiting and stops when the chlorinated layer is sufficiently thick to effectively block the reaction of the underlying titanium-containing film with the chlorine-containing gas. The chlorinated layer is easier to remove from the substrate than the titanium-containing film and therefore the exposure to the plasma-excited inert gas may be performed under mild plasma conditions that do not significantly remove or damage the underlying titanium-containing film and any devices on the substrate.

The method further includes, in 106, repeating the exposing steps 102 and 104 at least once to further etch the titanium-containing film. As used herein, a cycle refers to a process of sequentially performing the exposing step 102 and 104 once.

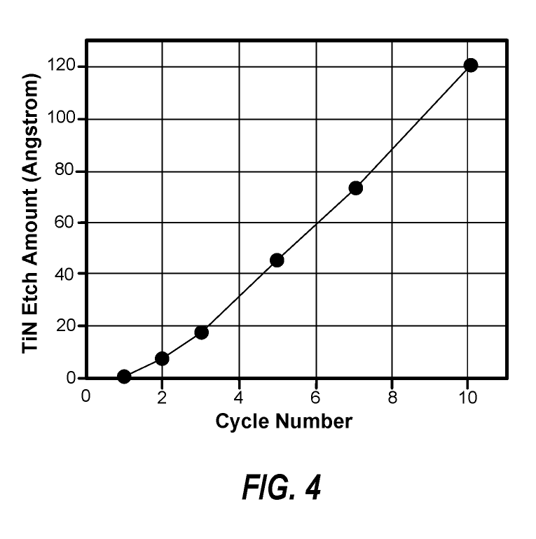

FIG. 4 shows TiN etching amounts as a function of number of cycles using alternating exposures of Cl₂ and plasma-excited Ar. The TiN film was etched at about 1 nm/cycle.

Exemplary processing conditions for exposure to the chlorine-containing gas include a gas pressure of less than about 500 mTorr, substrate temperature between about 10° C. and about 60° C., and a gas flow rate of less than about 200 sccm. In one example, the chlorine-containing gas can contain Cl₂, BCl₃, or chlorine radicals. The chlorine-containing gas can include an inert gas, e.g., Ar. According to one embodiment, the exposing the substrate to a chlorine-containing gas may performed in the absence of a plasma. According to another embodiment, the exposing the substrate to a chlorine-containing gas may be performed with plasma excitation. In one example, a plasma power of less than 1000 W may be used.

A gas purging step using an inert gas (a noble gas (e.g., Ar), N₂, or any other inert gas) may be performed following the exposure to the chlorine-containing gas and following the exposure to the plasma-excited inert gas. The processing conditions can include a gas pressure of less than about 500 mTorr, substrate temperature between about 10° C. and about 60° C., and a gas flow rate of less than about 1000 sccm.

Exemplary processing conditions for exposure to the plasma-excited inert gas include a gas pressure less than about 500 mTorr, substrate temperature between about 10° C. and about 60° C., a gas flow rate of less than about 1500 sccm, and a plasma power of less than 1000 W.

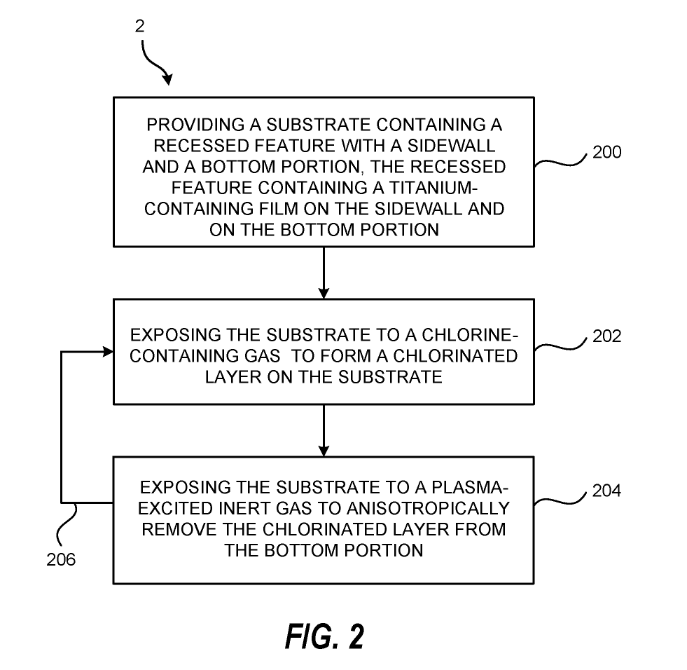

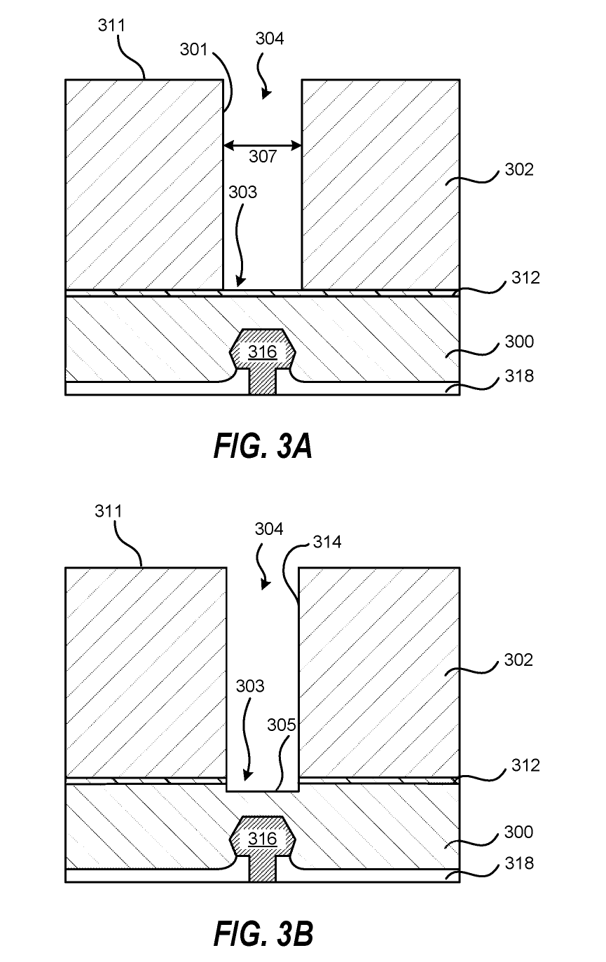

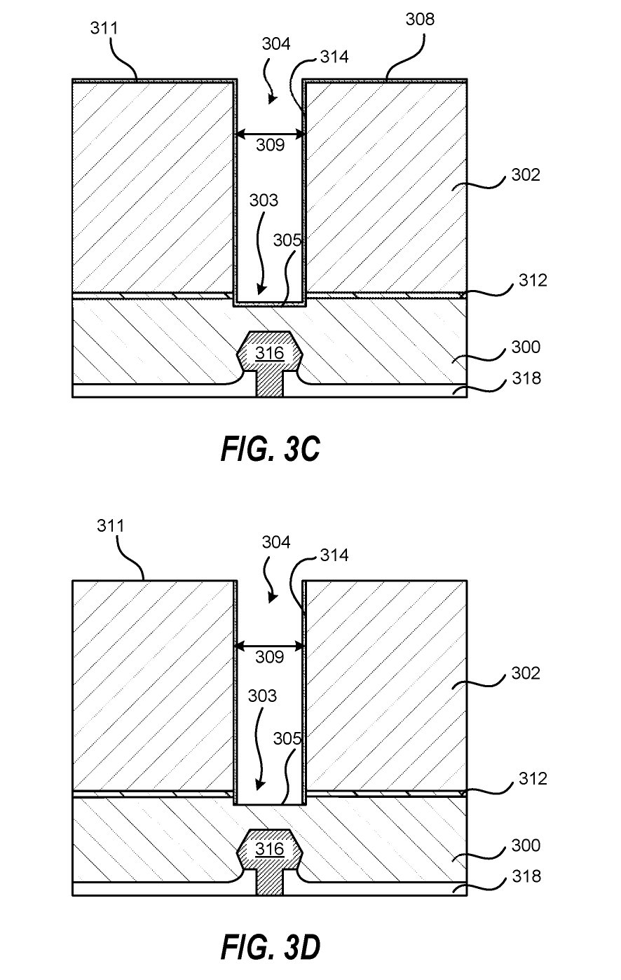

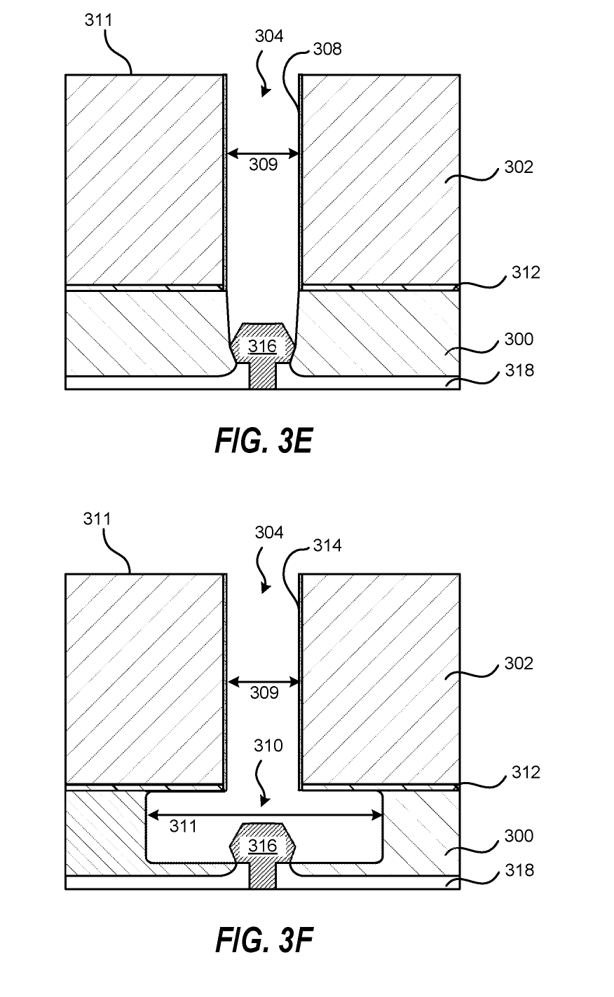

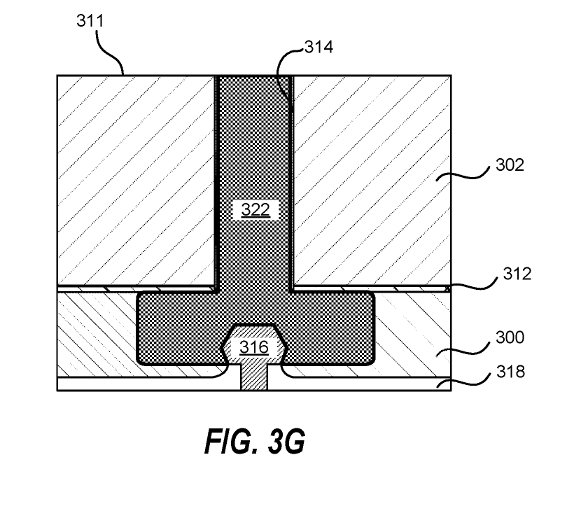

FIG. 2 is a process flow diagram for a method of processing as substrate according to an embodiment of the invention, and FIGS. 3A-3H schematically show through cross-sectional views a method of processing a substrate according to an embodiment of the invention.

FIG. 3A shows a substrate containing a raised contact 316 in a first dielectric film 300, and a second dielectric film 302 on the first dielectric film 300, where that second dielectric film 302 has a recessed feature 304 with a sidewall 301 and a bottom portion 303 above the raised contact 316. The substrate further includes an etch stop layer 312 on the first dielectric film 300, and a dielectric film 318 underneath the first dielectric film 300. The etch stop layer 312 may be used to terminate the etching during the formation of the recessed feature 304. The etch stop layer 312 may, for example, include a high-k material, silicon nitride, silicon oxide, carbon, or silicon.

The recessed feature 304 can, for example, have a width 307 that is less than 200 nm, less than 100 nm, less than 50 nm, less than 25 nm, less than 20 nm, or less than 10 nm. In other examples, the recessed feature 304 can have a width 307 that is between 5 nm and 10 nm, between 10 nm and 20 nm, between 20 nm and 50 nm, between 50 nm and 100 nm, between 100 nm and 200 nm, between 10 nm and 50 nm, or between 10 nm and 100 nm. The width 307 can also be referred to as a critical dimension (CD). The recessed feature 304 can, for example, have a depth of 25 nm, 50 nm, 100 nm, 200 nm, or greater. In some examples, the first dielectric film 300 may contain SiO₂, SiON, SiN, a high-k material, a low-k material, or an ultra-low k material. In some examples, the second dielectric film 302 may contain SiO₂, SiON, SiN, a high-k material, a low-k material, or an ultra-low k material.

The recessed feature 304 may the formed using well-known lithography and etching processes. Although not shown in FIG. 3A, a patterned mask layer may be present on the field area 311 and defining the opening of the recessed feature 304.

FIG. 3B shows the substrate following an anisotropic etching process that etches through the etch stop layer 312 on the bottom portion 303. This anisotropic etch process is often referred to as a “contact etch open” and may form a shallow recess 305 in the first dielectric film 300 after complete removal of the etch stop layer 312.

FIG. 3C shows a conformal titanium-containing film 308 deposited on the substrate, including on the sidewall 30, on the bottom portion 303, and on the shallow recess 305. According to one embodiment, the conformal titanium-containing film 308 may be deposited by ALD. ALD can deposit very thin films with atomic level thickness control and excellent conformality over advanced raised and recessed features. The titanium-containing film can, for example, include Ti metal, TiN, TiC, TiCN, or combinations thereof.

In some examples, a thickness of the conformal titanium-containing film can be 10 nm or less, 5 nm or less, 4 nm or less, between 1 nm and 2 nm, between 2 nm and 4 nm, between 4 nm and 6 nm, between 6 nm and 8 nm, or between 2 nm and 6 nm. The presence of the conformal titanium-containing film 308 on the sidewall 301 reduces the width 307 of the recessed feature 304 to a width 309. However, this change in width is relatively small since the conformal titanium-containing film 308 may be only a few nm thick.

Referring back to FIG. 2, after providing the substrate in 200, the process flow 2 includes removing the titanium-containing film 308 from the bottom portion 303 in an etching process, where the etching process includes, in 202, exposing the substrate to a chlorine-containing gas to form a chlorinated layer on the substrate and, in 204, exposing the substrate to a plasma-excited inert gas to anisotropically remove the chlorinated layer from the bottom portion and the shallow recess 305, and repeating the exposing steps 202 and 204 at least once. In one example, the remainder of the titanium-containing film 308 forms a protection film 314 on the sidewall 301 and defines a width 309 of the recessed feature 304. The resulting substrate is shown in FIG. 3D where the titanium-containing film 308 has been fully removed from the bottom portion 303. The anisotropic etching method for the titanium-containing film 308 is very well suited for such film removal since many contact applications required strict thickness, uniformity, and almost no margin or variation at the atomic level. Furthermore, many etching processes provide good etch selectivity between titanium-containing films and other materials used at the contact level of devices.

In one embodiment, the method further includes extending the recessed feature 304 to the raised contact 316 in the first dielectric film 300 using an anisotropic etching process. This is schematically shown in FIG. 3E. The protection film 314 has adequate thickness and etch resistance to prevent or reduce etching of the sidewall 301 during the anisotropic etching process, thus preventing loss of critical dimension.

The method further includes forming a cavity 310 containing the raised contact 316 in an isotropic etching process, where a width 311 of the cavity 310 is greater than the width 309 of the recessed feature 304. This is schematically shown in FIG. 3F. In some examples, the isotropic etching process can include thermal ALE, Chemical Oxide Removal (COR) using HF and NH₃, or dilute HF (DHF).

According to one embodiment, the method further includes depositing a contact metal (not shown) on the raised contact 316, and filling the recessed feature 304 and the cavity 310 with a metal 322. The contact metal may, for example, be selected from Ti, TiSi, NiSi, NiPtSi, Co, and CoSi. The metal 322 may, for example, be selected from the group consisting of W, Cu, Ru, and Co. This is schematically shown in FIG. 3G.

According to another embodiment, the step of forming the cavity 310 may be omitted and the substrate shown in FIG. 3E further processed by depositing a contact metal (not shown) on the raised contact 316, and filling the recessed feature 304 with a metal 322.

Methods for anisotropic dry etching of titanium-containing films used in semiconductor manufacturing have been disclosed in various embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A substrate processing method, comprising:
providing a substrate having a titanium-containing film thereon; and
etching the titanium-containing film in a dry etching process by:
a) exposing the substrate to a chlorine-containing gas to form a chlorinated layer on the substrate;
b) exposing the substrate to a plasma-excited inert gas to remove the chlorinated layer from the substrate; and
c) repeating the exposing steps at least once.

2. The method of claim 1, wherein the titanium-containing film contains Ti metal, TiN, TiC, TiCN, or combinations thereof.

3. The method of claim 1, wherein the substrate temperature is between about −10° C. and about 60° C.

4. The method of claim 1, wherein a gas pressure in the dry etching process is less than about 500 mTorr.

5. The method of claim 1, wherein the chlorine-containing gas contains Cl₂, BCl₃, or chlorine radicals.

6. The method of claim 1, wherein the chlorine-containing gas contains Cl₂ and Ar.

7. The method of claim 1, wherein the exposing the substrate to a chlorine-containing gas is performed in the absence of a plasma.

8. The method of claim 1, where the exposing the substrate to a chlorine-containing gas is performed with plasma excitation.

9. The method of claim 1, wherein the plasma-excited inert gas includes Ar or N₂.

10. A substrate processing method, comprising:
providing a substrate having a titanium-containing film thereon, wherein the titanium-containing film contains Ti metal, TiN, TiC, TiCN, or combinations thereof and
etching the titanium-containing film in a dry etching process by:
a) exposing the substrate to a chlorine-containing gas to form a chlorinated layer on the substrate, wherein the chlorine-containing gas contains Cl₂, BCl₃, or chlorine radicals;
b) exposing the substrate to a plasma-excited inert gas to remove the chlorinated layer from the substrate; and
c) repeating the exposing steps at least once.

11. The method of claim 10, wherein the chlorine-containing gas contains Cl₂ and Ar.

12. A substrate processing method, comprising:
providing a substrate containing a recessed feature with a sidewall and a bottom portion, the recessed feature containing a titanium-containing film on the sidewall and on the bottom portion; and
removing the titanium-containing film in a dry etching process from the bottom portion, but not from the sidewall, by:
a) exposing the substrate to a chlorine-containing gas to form a chlorinated layer on the bottom portion;
b) exposing the substrate to a plasma-excited inert gas to remove the chlorinated layer from the bottom portion; and
c) repeating the exposing steps at least once.

13. The method of claim 12, wherein the titanium-containing film contains Ti metal, TiN, TiC, TiCN, or combinations thereof.

14. The method of claim 12, wherein the substrate temperature is between about −10° C. and about 60° C.

15. The method of claim 12, wherein a gas pressure in the dry etching process is less than about 500 mTorr.

16. The method of claim 12, wherein the chlorine-containing gas contains Cl₂, BCl₃, or chlorine radicals.

17. The method of claim 12, wherein the chlorine-containing gas contains Cl₂ and Ar.

18. The method of claim 12, where the exposing the substrate to a chlorine-containing gas is performed in the absence of a plasma.

19. The method of claim 12, where the exposing the substrate to a chlorine-containing gas is performed with plasma excitation.

20. The method of claim 12, wherein the plasma-excited inert gas includes Ar or N₂.
